(19) United States
(12) Patent Application Publication
(10) Pub. No.: US 2025/0132224 A1
(43) Pub. Date: Apr. 24, 2025

(54) PRINTED CIRCUIT BOARD

(71) Applicant: SAMSUNG ELECTRO-MECHANICS CO., LTD., Suwon-si (KR)

(72) Inventors: Jung Chul GONG, Suwon-si (KR); Seung Eun LEE, Suwon-si (KR)

(73) Assignee: SAMSUNG ELECTRO-MECHANICS CO., LTD., Suwon-si (KR)

(21) Appl. No.: 18/790,090

(22) Filed: Jul. 31, 2024

(30) Foreign Application Priority Data
Oct. 19, 2023 (KR) 10-2023-0140049

(51) Int. Cl. H01L 23/373; H01L 23/00; H01L 29/417; H01L 29/45; H05K 1/11; H05K 1/18; H05K 3/42; H05K 3/46

(52) U.S. Cl. CPC H01L 23/3736; H01L 24/05; H01L 24/19; H01L 24/20; H05K 1/115; H05K 1/185; H05K 3/42; H05K 3/4673; H10D 64/252; H10D 64/62; H01L 2224/05573; H01L 2224/05647; H01L 2224/19; H01L 2224/2101; H01L 2224/211; H01L 2224/214; H01L 2924/13091; H05K 2201/0792; H05K 2201/09072; H05K 2201/09509; H05K 2201/09563; H05K 2201/096; H05K 2201/10166; H05K 2203/061; H05K 2203/107; H05K 2203/1316

(57) ABSTRACT

A printed circuit board includes: a substrate having a cavity; a semiconductor device at least partially disposed in the cavity, with a first metal pad and a gate being disposed on a lower side of the semiconductor device and a second metal pad being disposed on an upper side of the semiconductor device; a metal block at least partially disposed in the cavity, the metal block being connected to the second metal pad; and a first insulating layer covering at least a portion of each of the substrate, the semiconductor device, and the metal block, and filling at least a portion of the cavity.

### CROSS-REFERENCE TO RELATED APPLICATION(S)

This application claims the benefit of priority to Korean Patent Application No. 10-2023-0140049 filed on Oct. 19, 2023 in the Korean Intellectual Property Office, the disclosure of which is incorporated herein by reference in its entirety.

### TECHNICAL FIELD

The present disclosure relates to a printed circuit board.

### BACKGROUND

A recent trend is for electronic components applied to electronic devices for electronic equipment to be light, thin, short, and small according to increases of I/O. For this reason, there is a demand for embedding a semiconductor device, e.g., a power device, in a printed circuit board.

### SUMMARY

An aspect of the present disclosure is to provide a printed circuit board in which a semiconductor device, e.g., a power device, is embedded.

Another aspect of the present disclosure is to provide a printed circuit board capable of reducing power loss by reducing a parasitic resistance of a power device.

Another aspect of the present disclosure is to provide a printed circuit board having improved heat dissipation characteristics by smoothly dissipating heat from a power device.

One of several solutions suggested through the present disclosure is to dispose and embed a semiconductor device, e.g., a power device, in a cavity of a substrate, with a metal block being connected to the semiconductor device.

According to an aspect of the present disclosure, a printed circuit board includes: a substrate having a cavity; a semiconductor device of which at least a portion is disposed in the cavity, with a first metal pad being disposed on a lower side of the semiconductor device and a second metal pad being disposed on an upper side of the semiconductor device; a metal block of which at least a portion is disposed in the cavity, the metal block being connected to the second metal pad; and a first insulating layer covering at least a portion of each of the substrate, the semiconductor device, and the metal block, and filling at least a portion of the cavity.

According to another aspect of the present disclosure, a printed circuit board includes: a substrate having a through-cavity; a laminate of which at least a portion is disposed in the through-cavity, the laminate including a power device with a first metal pad and a gate being disposed on one side of the power device and a second metal pad being disposed on the other side of the power device, and a metal block disposed on the power device and contacting the second metal pad; and an insulating layer covering at least a portion of each of the substrate and the laminate, and filling at least a portion of the through-cavity.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram illustrating an example of an electronic device system;

FIG. 2 is a schematic perspective view illustrating an example of an electronic device;

FIG. 3 is a schematic cross-sectional view illustrating an example of a printed circuit board;

FIGS. 4A to 4E are schematic cross-sectional views illustrating examples of processes for manufacturing the printed circuit board of FIG. 3;

FIG. 5 is a schematic cross-sectional view illustrating a printed circuit board according to another example;

FIGS. 6A to 6H are schematic cross-sectional views illustrating examples of processes for manufacturing the printed circuit board of FIG. 5;

FIG. 7 is a schematic cross-sectional view illustrating a printed circuit board according to another example;

FIGS. 8A to 8H are schematic cross-sectional views illustrating examples of processes for manufacturing the printed circuit board of FIG. 7;

FIG. 9 is a schematic cross-sectional view illustrating a printed circuit board according to another example;

FIGS. 10A to 10I are schematic cross-sectional views illustrating examples of processes for manufacturing the printed circuit board of FIG. 9;

FIG. 11 is a schematic cross-sectional view illustrating a printed circuit board according to another example; and

FIGS. 12A to 12I are schematic cross-sectional views illustrating examples of processes for manufacturing the printed circuit board of FIG. 11.

### DETAILED DESCRIPTION

Hereinafter, the present disclosure will be described with reference to the accompanying drawings. The shapes and sizes of elements in the drawings may be exaggerated or reduced for clearer explanation.

### Electronic Device

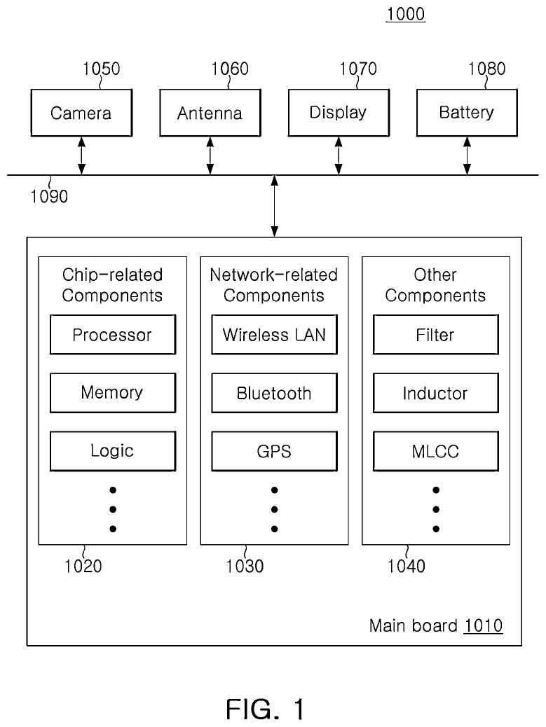

FIG. 1 is a schematic block diagram illustrating an example of an electronic device system.

Referring to FIG. 1, an electronic device 1000 may accommodate a mainboard 1010 therein. The mainboard 1010 may include chip-related components 1020, network-related components 1030, and other components 1040, which are physically and/or electrically connected thereto. These components may be connected to other electronic components to be described below to form various signal lines 1090.

The chip-related components 1020 may include a memory chip such as a volatile memory (e.g., a dynamic random access memory (DRAM)), a non-volatile memory (e.g., a read only memory (ROM)), or a flash memory; an application processor chip such as a central processor (e.g., a central processing unit (CPU)), a graphics processor (e.g., a graphics processing unit (GPU)), a digital signal processor, a cryptographic processor, a microprocessor, or a microcontroller; a logic chip such as an analog-to-digital converter or an application-specific integrated circuit (ASIC); and the like. The chip-related components 1020 are not limited thereto, and may also include other types of chip-related electronic components. In addition, the chip-related components 1020 may be combined with each other. The chip-related components 1020 may be in the form of a package including the chips or electronic components described above.

The network-related components 1030 may include protocols such as wireless fidelity (Wi-Fi) (Institute of Electrical and Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+ (HSPA+), high speed downlink packet access+ (HSDPA+), high speed uplink packet access+ (HSUPA+), global system for mobile communications (GSM), enhanced data GSM environment (EDGE), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the abovementioned protocols. However, the network-related components 1030 are not limited thereto, and may also include a variety of other wireless or wired standards or protocols. In addition, the network-related components 1030 may be combined with each other, together with the chip-related components 1020.

The other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and also include passive elements in chip component type used for various other purposes, and the like. In addition, the other components 1040 may be combined with each other, together with the chip-related components 1020 and/or the network-related components 1030.

Depending on the type of electronic device 1000, the electronic device 1000 may include other electronic components that may or may not be physically and/or electrically connected to the mainboard 1010. Examples of the other electronic components may include a camera 1050, an antenna 1060, a display 1070, a battery 1080, and the like. The other electronic components are not limited thereto, but may be an audio codec, a video codec, a power amplifier, a compass, an accelerometer, a gyroscope, a speaker, a mass storage unit (e.g., a hard disk drive), a compact disk (CD), a digital versatile disk (DVD), and the like. The other electronic components may also include other electronic components and the like used for various purposes depending on the type of electronic device 1000.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

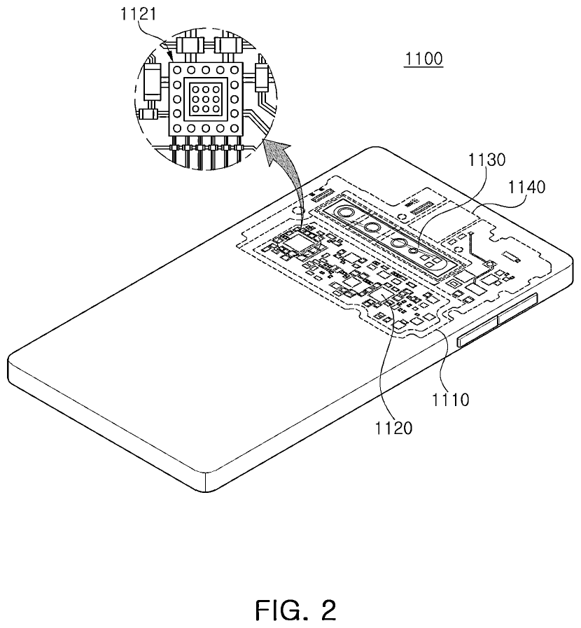

FIG. 2 is a schematic perspective view illustrating an example of an electronic device.

Referring to FIG. 2, the electronic device may be, for example, a smartphone 1100. A motherboard 1110 may be accommodated in the smartphone 1100, and various components 1120 may be physically and/or electrically connected to the motherboard 1110. Also, other components that may or may not be physically and/or electrically connected to the motherboard 1110, such as a camera module 1130 and/or a speaker 1140, may be accommodated in the smartphone 1100. Some of the components 1120 may be the above-described chip-related components, e.g., a component package 1121, but are not limited thereto. The component package 1121 may be in the form of a printed circuit board on which electronic components including active components and/or passive components are surface-mounted. Alternatively, the component package 1121 may be in the form of a printed circuit board in which active components and/or passive components are embedded. Meanwhile, the electronic device is not necessarily limited to the smartphone 1100, but may be any other electronic device as described above.

### Printed Circuit Board

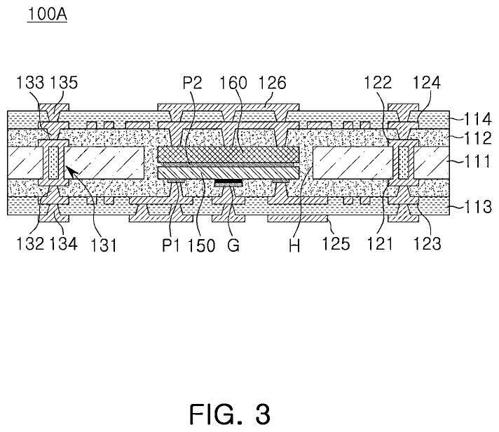

FIG. 3 is a schematic cross-sectional view illustrating an example of a printed circuit board.

Referring to FIG. 3, a printed circuit board 100A according to an example may include a substrate 111 having a cavity H, a semiconductor device 150 of which at least a portion is disposed in the cavity H, a metal block 160 of which at least a portion is disposed in the cavity H, the metal block 160 being connected to the semiconductor device 150, and a first insulating layer 112 covering at least a portion of each of the substrate 111, the semiconductor device 150, and the metal block 160 and filling at least a portion of the cavity H. The semiconductor device 150 and the metal block 160 may be disposed in the cavity H penetrating between upper and lower surfaces of the substrate 111 in the form of a laminate, and buried in the first insulating layer 112. A first metal pad P1 and a second metal pad P2 may be disposed on lower and upper sides of the semiconductor device 150, respectively. The metal block 160 may be attached to and/or contact the second metal pad P2 of the semiconductor device 150. For example, the metal block 160 may be directly connected to the second metal pad P2 of the semiconductor device 150. A gate G may further be disposed on the lower side of the semiconductor device 150. The semiconductor device 150 may be a power device, and may include, for example, a power MOSFET. At this time, the first and second metal pads P1 and P2 may include a source pad and a drain pad, respectively.

Meanwhile, the power device, for example, a power MOSFET, may have a vertical structure in which a source and a gate are disposed on one side and a drain is disposed on the other side. At this time, even a small parasitic resistance in an area where a large current flows between the drain and the source may reduce efficiency and generate a lot of heat. Therefore, shortening this path may be effective in improving the performance of the power MOSFET. Meanwhile, when it is attempted to embed the power MOSFET structure in the cavity of the substrate, a thickness of the substrate may be secured at a certain level or higher, because a problem may occur during a substrate manufacturing process if the thickness of the substrate is too thin. In this state, if only the power MOSFET is manufactured thinly, various problems such as underfilling and undulation may occur during the process of embedding the power MOSFET in the substrate. Therefore, it may be necessary to manufacture a power MOSFET having a considerable thickness and embed the power MOSFET in the substrate, but in this case, a parasitic resistance may increase, power loss may increase, and a large amount of heat may be generated.

In contrast, in the printed circuit board 100A according to an example, even though the substrate 111 is formed to be thick, the semiconductor device 150 that is thinly processed to reduce parasitic resistance, for example, a power device such as a power MOSFET, can be easily embedded. Specifically, in an example, the semiconductor device 150 can be disposed in the cavity H of the substrate 111, with the metal block 160 attached to the semiconductor device 150. In this case, even though the semiconductor device 150 is thin, the metal block 160 may be formed relatively thick to correspond to the thickness of the substrate 111. For example, the metal block 160 may be thicker than the semiconductor device 150. Therefore, in a case where a power device such as a power MOSFET is embedded, a size of a system be reduced, and power loss can also be reduced by reducing a parasitic resistance component, resulting in an improvement in system efficiency. In addition, heat can be smoothly dissipated from the power device, thereby improving dissipation characteristics.

Additionally, a problem such as underfilling or undulation can be improved. Meanwhile, the semiconductor device 150 and the metal block 160 may be disposed in the cavity H of the substrate 111 in the form of one laminate. For example, the semiconductor device 150 and the metal block 160 may be similarly sized and then joined to form a laminate. Alternatively, a laminate may be formed by joining a semiconductor wafer and a metal plate to each other and then performing a dicing process. At this time, the metal block 160 may be directly connected to the second metal pad P2 of the semiconductor device 150. For example, each of the second metal pad P2 and the metal block 160 may include copper (Cu). For example, the second metal pad P2 may be a drain pad made of copper (Cu), and the metal block 160 may be a copper block (Cu block). Therefore, the second metal pad P2 and the metal block 160 may be directly connected to each other through a copper (Cu)-copper (Cu) junction. In this case, no separate adhesive can be necessary, and junction reliability can be superior.

Referring to FIG. 3, the printed circuit board 100A according to an example may further include a first wiring layer 121 disposed on the lower surface of the substrate 111, a second wiring layer 122 disposed on the upper surface of the substrate 111, a first via layer 131 penetrating the substrate 111 and connecting the first and second wiring layers 121 and 122 to each other, a third wiring layer 123 disposed on a lower surface of the first insulating layer 112, a second via layer 132 penetrating at least a portion of the first insulating layer 112 on a lower side thereof and connecting the third wiring layer 123 to the first wiring layer 121, the first metal pad P1, and the gate G, a fourth wiring layer 124 disposed on an upper surface of the first insulating layer 112, a third via layer 133 penetrating at least a portion of the first insulating layer 112 on an upper side thereof and connecting the fourth wiring layer 124 to the second wiring layer 122 and the metal block 160, a second insulating layer 113 disposed on the lower surface of the first insulating layer 112, a fifth wiring layer 125 disposed on a lower surface of the second insulating layer 113, a fourth via layer 134 penetrating at least a portion of the second insulating layer 113 and connecting the fifth wiring layer 125 to the third wiring layer 123, a third insulating layer 114 disposed on the upper surface of the first insulating layer 112, a sixth wiring layer 126 disposed on an upper surface of the third insulating layer 114, and/or a fifth via layer 135 penetrating at least a portion of the third insulating layer 114 and connecting the sixth wiring layer 126 to the fourth wiring layer 124. The second via layer 132 may include a first metal via connected to the first metal pad P1 and a second metal via connected to the gate G. The third via layer 133 may include a third metal via connected to the metal block 160.

For example, the printed circuit board 100A according to an example may have a multi-layer wiring structure. At this time, the first metal pad P1 and the gate G of the semiconductor device 150 may be electrically connected to the wiring through the first and second metal vias. In addition, the second metal pad P2 of the semiconductor device 150 may be electrically connected to the wiring through the third metal via and the metal block 160, moreover causing an excellent heat dissipation effect. Meanwhile, the third metal via may be deeper than the second metal via, but is not limited thereto.

Hereinafter, the components of the printed circuit board 100A according to an example will be described in more detail with reference to the drawings.

The substrate 111 may be a core layer. For example, the substrate 111 may include an organic core layer, a glass core layer, a metal core layer, a silicon core layer, or a ceramic core layer. The organic core layer may include an organic insulating material. The organic insulating material may include a thermosetting resin such as an epoxy resin, a thermoplastic resin such as polyimide, or a material containing an inorganic filler, an organic filler, and/or a glass fiber, glass cloth, or glass fabric together with a resin. For example, the organic insulating material may be a non-photosensitive insulating material such as copper clad laminate (CCL), Ajinomoto build-up film (ABF), or prepreg (PPG), but is not limited thereto, and another polymer material may be used. The glass core layer may include glass. The glass may include, for example, pure silicon dioxide (about 100% SiO₂), soda lime glass, borosilicate glass, alumino-silicate glass, or the like. However, the glass core layer is not limited thereto, and an alternative glass material, e.g., fluorine glass, phosphate glass, or chalcogen glass, may also be used as a material for the glass layer. In addition, the glass core layer may further include other additives to form glass with specific physical properties. These additives may include not only calcium carbonate (e.g., lime) and sodium carbonate (e.g., soda), but also magnesium, calcium, manganese, aluminum, lead, boron, iron, chromium, potassium, sulfur, and antimony, as well as carbonates and/or oxides of these and other elements. The glass may be distinguished from the aforementioned glass fiber, glass cloth, or glass fabric. The metal core layer may include a metal. The metal may include, for example, copper (Cu), Invar, or the like, but is not limited thereto. The silicon core layer may include pure silicon (Si). If necessary, the silicon core layer may include an oxide layer formed on silicon (Si). In addition, the silicon core layer may include a nitride layer formed on the oxide layer. The oxide layer may include a silicon oxide film, and the nitride layer may include a silicon nitride film, but the oxide layer and the nitride layer are not limited thereto. The ceramic core layer may include a ceramic material. The ceramic material may include, for example, alumina (Al₂O₃), aluminum nitride (AlN), silicon carbide (SiC), silicon nitride (Si₃N₄), or the like, but is not limited thereto.

The first to third insulating layers 112, 113, and 114 may include an organic insulating material. As described above, the organic insulating material may include a thermosetting resin such as an epoxy resin, a thermoplastic resin such as polyimide, or a material containing an inorganic filler, an organic filler, and/or a glass fiber, glass cloth, or glass fabric together with a resin. For example, the organic insulating material may be a non-photosensitive insulating material such as copper clad laminate (CCL), Ajinomoto build-up film (ABF), or prepreg (PPG), but is not limited thereto, and another polymer material may be used. The first to third insulating layers 112, 113, and 114 may include the same organic insulating material or different organic insulating materials. Each of the first to third insulating layers 112, 113, and 114 may include multiple layers if necessary.

Each of the first to sixth wiring layers 121, 122, 123, 124, 125, and 126 may include a metal material. The metal material may include copper (Cu), aluminum (Al), silver (Ag), tin (Sn), gold (Au), nickel (Ni), lead (Pb), titanium (Ti), and/or an alloy thereof. Preferably, the metal material may include copper (Cu), but is not limited thereto. The first to sixth wiring layers 121, 122, 123, 124, 125, and 126 may perform various functions depending on respective designs. For example, the first to sixth wiring layers 121, 122, 123, 124, 125, and 126 may include signal patterns, power patterns, ground patterns, and the like. These patterns may have various forms such as lines, planes, and pads, respectively. Each of the first to sixth wiring layers 121, 122, 123, 124, 125, and 126 may include a seed layer and a plating layer formed on the seed layer. The seed layer may be an electroless plating layer (or chemical copper) and/or a sputtering layer, and the plating layer may be an electrolytic plating layer (or electrical copper), but the seed layer and the plating layer are not limited thereto.

Each of the first to fifth via layers 131, 132, 133, 134, and 135 may include a metal material. As described above, the metal material may include copper (Cu), aluminum (Al), silver (Ag), tin (Sn), gold (Au), nickel (Ni), lead (Pb), titanium (Ti), and/or an alloy thereof. Preferably, the metal material may include copper (Cu), but is not limited thereto. The first via layer 131 may include a through metal via. The through metal via may be formed by disposing a metal layer including the above-described metal material on an inner wall of a through-hole and filling the inside of the through-hole with a filler. The filler may be an insulating ink containing an insulating resin such as epoxy, but is not limited thereto, and may include a conductive ink if necessary. Each of the second to fifth via layers 132, 133, 134, and 135 may include micro metal vias. Each of the micro metal vias may include a filled VIA filling a via hole, but may also include a conformal VIA disposed along a wall surface of a via hole. The second and third via layers 132 and 133 may be tapered in opposite directions. The fourth and fifth via layers 134 and 135 may be tapered in opposite directions. The second and fourth via layers 132 and 134 may be tapered in the same direction. The third and fifth via layers 133 and 135 may be tapered in the same direction. The first to fifth via layers 131, 132, 133, 134, and 135 may perform various functions depending on respective designs. For example, the first to fifth via layers 131, 132, 133, 134, and 135 may include ground vias, power vias, signal vias, and the like. Each of the first to fifth via layers 131, 132, 133, 134, and 135 may include an electroless plating layer (or chemical copper) and an electrolytic plating layer (or electrical copper). Each of the first to fifth via layers 131, 132, 133, 134, and 135 may include a sputtering layer instead of the electroless plating layer (or chemical copper), or may include both the electroless plating layer (or chemical copper) and the sputtering layer.

The semiconductor device 150 may be an integrated circuit (IC) die in which hundreds to millions of devices are integrated into one chip. The IC die may be formed based on an active wafer. In this case, silicon (Si), germanium (Ge), gallium arsenide (GaAs), or the like may be used as a base material of each body. Various circuits may be formed on the body. The first and second metal pads P1 and P2 and the gate G may be formed on the body to be connected to external circuits, such as signals, electricity, and ground. Each of the first and second metal pads P1 and P2 may include a conductive material such as aluminum (Al) or copper (Cu). Each of the first and second metal pads P1 and P2 may be pads for connecting a source and a drain, respectively. For example, the semiconductor device 150 may preferably be a power device, and more preferably a power MOSFET, but is not limited thereto.

The metal block 160 may include a metal material. As described above, the metal material may include copper (Cu), aluminum (Al), silver (Ag), tin (Sn), gold (Au), nickel (Ni), lead (Pb), titanium (Ti), and/or an alloy thereof. Preferably, the metal material may include copper (Cu), and for example, the metal block 160 may be a copper block, but is not limited thereto. The metal block 160 may be in the form of a block having a square shape in a cross-sectional view, but is not limited thereto.

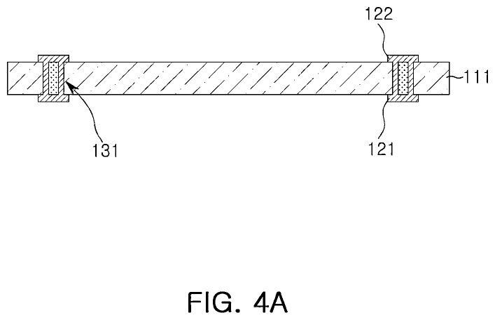

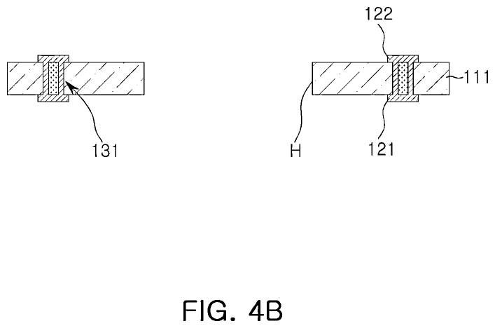

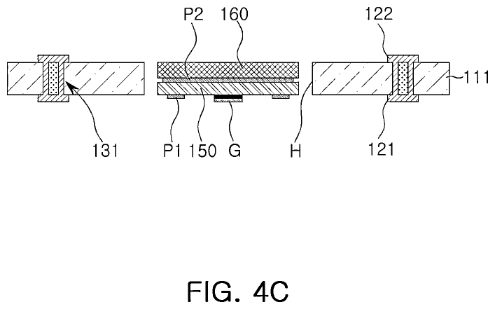

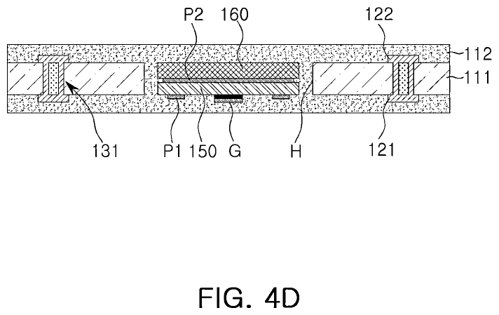

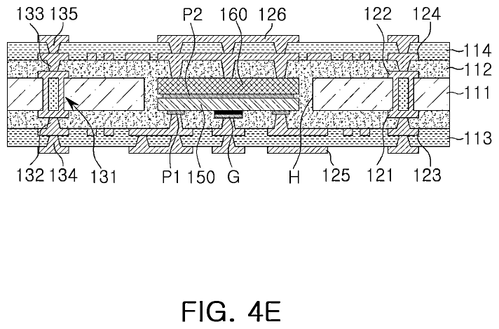

FIGS. 4A to 4E are schematic cross-sectional views illustrating examples of processes for manufacturing the printed circuit board of FIG. 3.

Referring to FIG. 4A, a substrate 111 may be prepared, and first and second wiring layers 121 and 122 and a first via layer 131 may be formed on and in the substrate 111. The substrate 111 may have various types of materials as described above, and the type of material may be selected according to need. A through-via hole for forming the first via layer 131 may be formed by any of various methods such as a laser drilling process, a mechanical drilling process, a chemical etching process, and a blasting process, depending on the material of the substrate 111. The first and second wiring layers 121 and 122 may be formed by a plating process. The first via layer 131 may be formed through a plating process and, if necessary, a plugging process.

Referring to FIG. 4B, a cavity H may be formed in the substrate 111. The cavity H may be a through-cavity penetrating between upper and lower surfaces of the substrate 111. The cavity H may be formed by any of various methods, such as a laser drilling process, a mechanical drilling process, a chemical etching process, and a blasting process, depending on the material of the substrate 111.

Referring to FIG. 4C, after forming a laminate by stacking a metal block 160 on a semiconductor device 150, the laminate may be disposed in the cavity H. In order to dispose the laminate, an adhesive such as a die attach film (DAF) may be used. For example, the laminate may be disposed in the cavity H by attaching the adhesive onto the lower surface of the substrate 111 and attaching the laminate to the adhesive exposed through the cavity H.

Referring to FIG. 4D, the substrate 111 and the laminate may be buried by a first insulating layer 112. For example, upper portions of the substrate 111 and the laminate may be covered by stacking a first layer of the first insulating layer 112 on the above-described adhesive, and thereafter lower portions of the substrate 111 and the laminate be covered by removing the adhesive and then stacking a second layer of the first insulating layer 112 on the area from which the adhesive is removed.

Referring to FIG. 4E, third and fourth wiring layers 123 and 124 and second and third via layers 132 and 133 may be formed on and in the first insulating layer 112. Via holes for forming the second and third via layers 132 and 133 may be formed by laser processing, mechanical drilling, or the like. The third and fourth wiring layers 123 and 124 and the second and third via layers 132 and 133 may be formed through a plating process. In addition, a build-up process may be performed, if necessary, to build second and third insulating layers 113 and 114, fifth and sixth wiring layers 125 and 126, and fourth and fifth via layers 134 and 135.

The above-described printed circuit board 100A according to an example may be manufactured through a series of processes, and other redundant descriptions will be omitted.

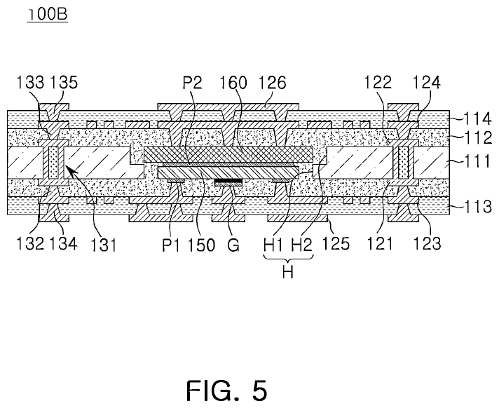

FIG. 5 is a schematic cross-sectional view illustrating a printed circuit board according to another example.

Referring to FIG. 5, in a printed circuit board 100B according to another example when compared to the above-described printed circuit board 100A according to an example, the cavity H may include a first cavity H1 penetrating at least a portion of the substrate 111 from the lower surface of the substrate 111 in the thickness direction, and a second cavity H2 penetrating at least another portion of the substrate 111 from the upper surface of the substrate 111 in the thickness direction. The first and second cavities H1 and H2 may be connected to each other in the thickness direction. At least a portion of the semiconductor device 150 may be disposed in the first cavity H1. At least a portion of the metal block 160 may be disposed in the second cavity H2. If necessary, the first and second cavities H1 and H2 may have different widths in a cross-sectional view. For example, the second cavity H2 may be wider than the first cavity H1 in a cross-sectional view. Correspondingly, the semiconductor device 150 and the metal block 160 may also have different widths in a cross-sectional view. For example, the metal block 160 may be wider than the semiconductor device 150 in a cross-sectional view. The metal block 160 may be directly connected to the second metal pad P2 of the semiconductor device 150, but is not limited thereto. If necessary, an adhesive such as a DAF may be disposed between the semiconductor device 150 and the metal block 160. In this way, after forming the first and second cavities H1 and H2 separately, the semiconductor device 150 and the metal block 160 may be disposed separately and then connected to each other. In this case as well, all of the above-described effects can be achieved. Other redundant descriptions will be omitted.

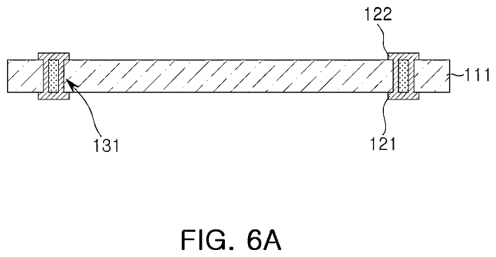

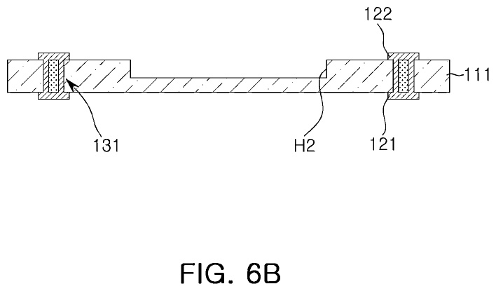

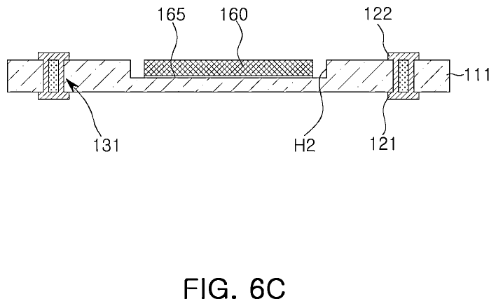

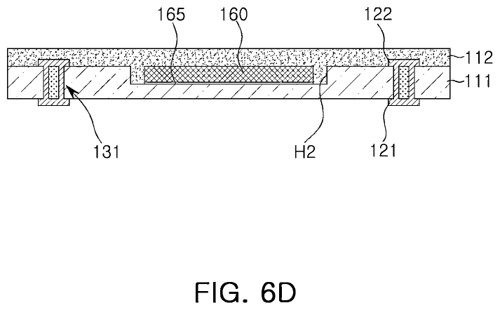

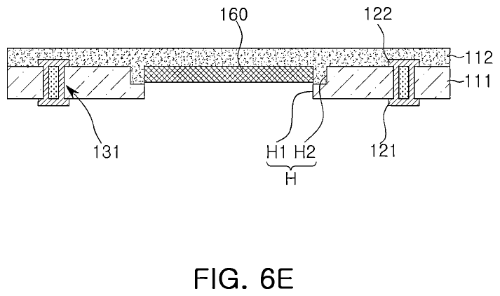

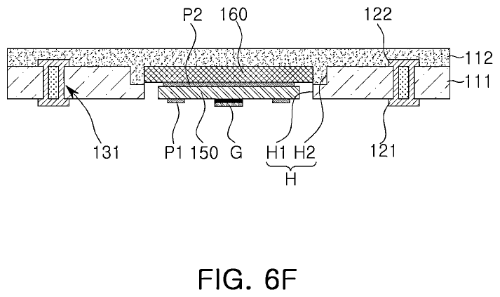

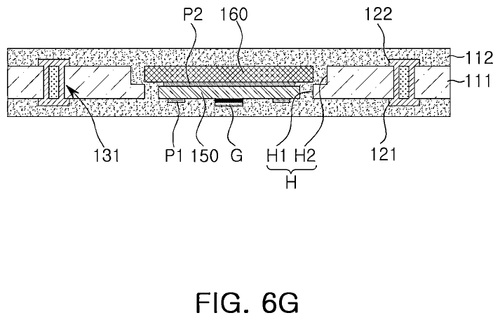

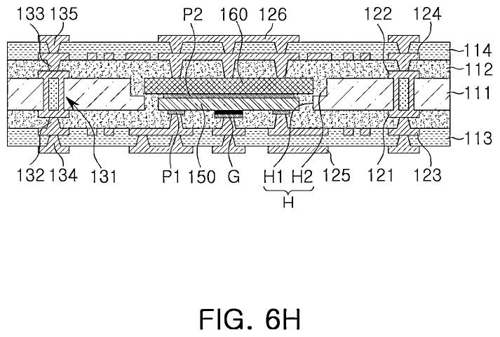

FIGS. 6A to 6H are schematic cross-sectional views illustrating examples of processes for manufacturing the printed circuit board of FIG. 5.

Referring to FIG. 6A, a substrate 111 may be prepared, and first and second wiring layers 121 and 122 and a first via layer 131 may be formed on and in the substrate 111. The substrate 111 may have various types of materials as described above, and the type of material may be selected according to need. A through-via hole for forming the first via layer 131 may be formed by any of various methods such as a laser drilling process, a mechanical drilling process, a chemical etching process, and a blasting process, depending on the material of the substrate 111. The first and second wiring layers 121 and 122 may be formed by a plating process. The first via layer 131 may be formed through a plating process and, if necessary, a plugging process.

Referring to FIG. 6B, a second cavity H2 may be formed in the substrate 111. The second cavity H2 may be a blind cavity penetrating a portion of the substrate 111 from the upper surface of the substrate 111. The second cavity H2 may be formed by any of various methods, such as a laser drilling process, a mechanical drilling process, a chemical etching process, and a blasting process, depending on the material of the substrate 111.

Referring to FIG. 6C, the metal block 160 may be disposed in the second cavity H2. For example, the metal block 160 may be attached onto a bottom surface of the second cavity H2 using an adhesive 165 such as a DAF.

Referring to FIG. 6D, the substrate 111 and the metal block 160 may be buried by a first layer of the first insulating layer 112. For example, the substrate 111 and the metal block 160 may be covered by stacking the first layer of the first insulating layer 112 on the substrate 111.

Referring to FIG. 6E, a first cavity H1 may be formed in the substrate 111. The first cavity H1 may be a blind cavity penetrating another portion of the substrate 111 from the lower surface of the substrate 111. If necessary, the adhesive 165 may be removed. The first cavity H1 may be connected to the second cavity H2. The second cavity H2 may be formed by any of various methods, such as a laser drilling process, a mechanical drilling process, a chemical etching process, and a blasting process, depending on the material of the substrate 111.

Referring to FIG. 6F, a semiconductor device 150 may be disposed in the first cavity H1. For example, the semiconductor device 150 may be disposed in the first cavity H1 in such a manner that the second metal pad P2 of the semiconductor device 150 is connected to the metal block 160.

Referring to FIG. 6G, the substrate 111 and the semiconductor device 150 may be buried by a second layer of the first insulating layer 112. For example, the substrate 111 and the semiconductor device 150 may be covered by stacking the second layer of the first insulating layer 112 on the substrate 111.

Referring to FIG. 6H, third and fourth wiring layers 123 and 124 and second and third via layers 132 and 133 may be formed on and in the first insulating layer 112. Via holes for forming the second and third via layers 132 and 133 may be formed by laser processing, mechanical drilling, or the like. The third and fourth wiring layers 123 and 124 and the second and third via layers 132 and 133 may be formed through a plating process. In addition, a build-up process may be performed, if necessary, to build second and third insulating layers 113 and 114, fifth and sixth wiring layers 125 and 126, and fourth and fifth via layers 134 and 135.

The above-described printed circuit board 100B according to another example may be manufactured through a series of processes, and other redundant descriptions will be omitted.

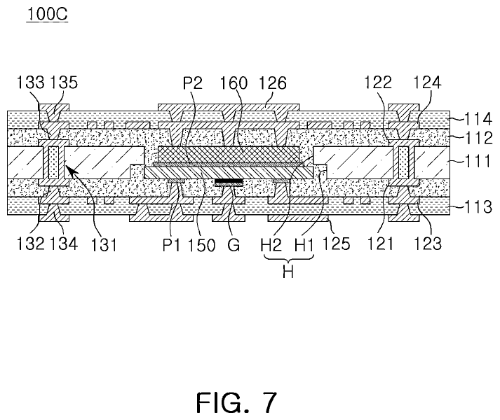

FIG. 7 is a schematic cross-sectional view illustrating a printed circuit board according to another example.

Referring to FIG. 7, in a printed circuit board 100C according to another example when compared to the above-described printed circuit board 100B according to another example, the first cavity H1 may be wider than the second cavity H2 in a cross-sectional view. Correspondingly, the semiconductor device 150 may be wider than the metal block 160 in a cross-sectional view. For example, the sizes of the first and second cavities H1 and H2 may be variously formed according to the sizes of the semiconductor device 150 and the metal block 160. In this case as well, all of the above-described effects can be achieved. Other redundant descriptions will be omitted.

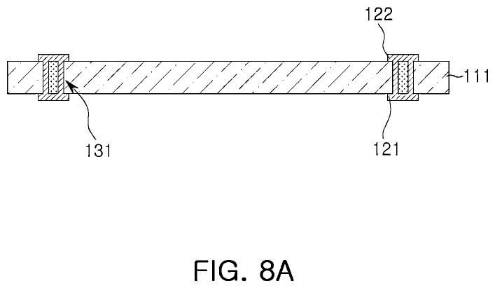

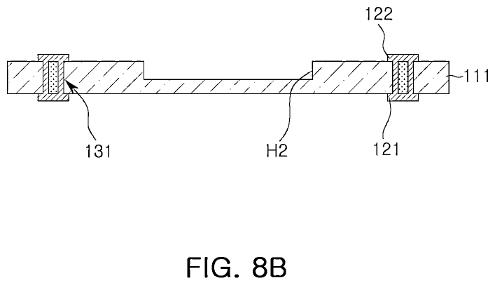

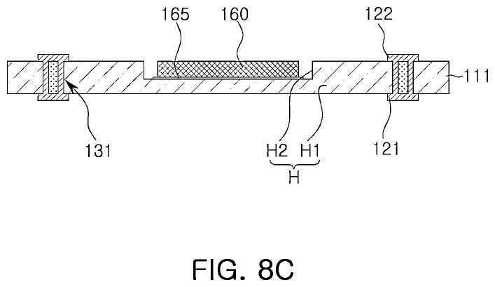

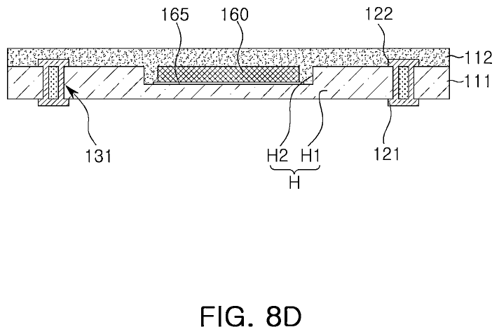

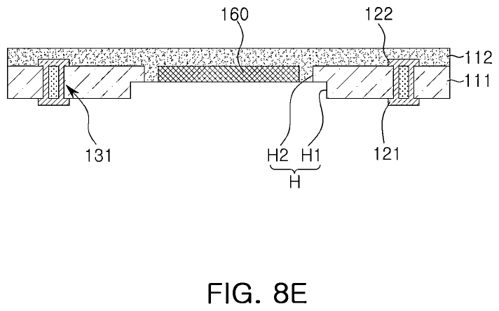

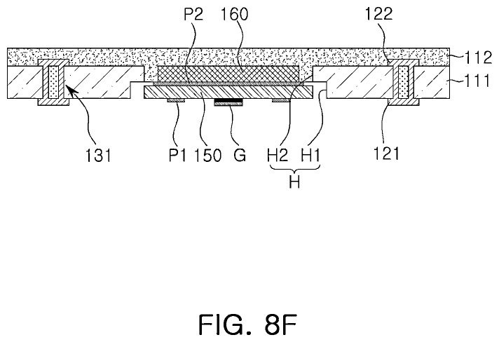

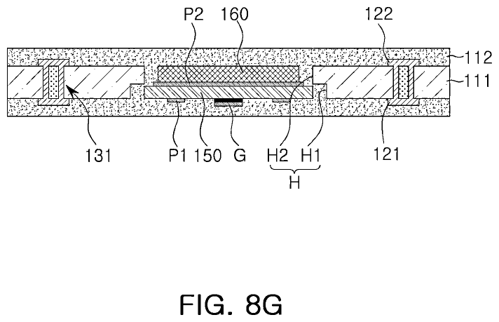

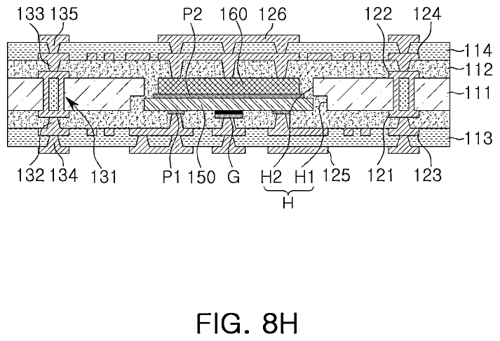

FIGS. 8A to 8H are schematic cross-sectional views illustrating examples of processes for manufacturing the printed circuit board of FIG. 7.

Referring to FIGS. 8A to 8H, the printed circuit board 100C according to another example may be manufactured through processes that are substantially the same as the above-described processes with reference to FIGS. 6A to 6H, except that the sizes of the first and second cavities H1 and H2 and the sizes of the semiconductor device 150 and the metal block 160 disposed in the first and second cavities H1 and H2 are different.

The above-described printed circuit board 100C according to another example may be manufactured through a series of processes, and other redundant descriptions will be omitted.

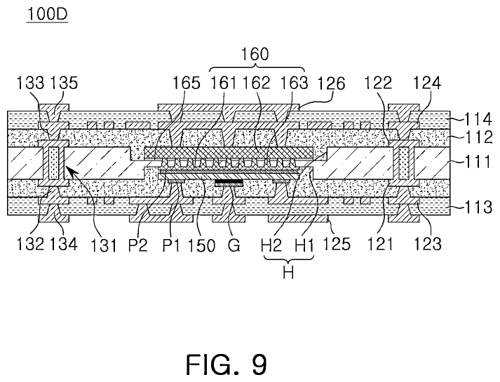

FIG. 9 is a schematic cross-sectional view illustrating a printed circuit board according to another example.

Referring to FIG. 9, in a printed circuit board 100D according to another example when compared to the above-described printed circuit board 100A according to an example, the cavity H may include a first cavity H1 penetrating at least a portion of the substrate 111 from the lower surface of the substrate 111 in the thickness direction, and a second cavity H2 penetrating at least another portion of the substrate 111 from the upper surface of the substrate 111 in the thickness direction. The substrate 111 may be disposed between the first and second cavities H1 and H2, thereby separating the first and second cavities H1 and H2 from each other. The metal block 160 may include a first metal block 161 of which at least a portion is disposed in the first cavity H1, the first metal block 161 being connected to the second metal pad P2, a second metal block 162 of which at least a portion is disposed in the second cavity H2, the second metal block 162 being attached onto the substrate 111 disposed between the first and second cavities H1 and H2 through an adhesive 165, and a metal via 163 penetrating the substrate 111 disposed between the first and second cavities H1 and H2 and the adhesive 165 and connecting the first and second metal blocks 161 and 162 to each other. The first metal block 161 and the second metal pad P2 may be directly connected to each other through a copper (Cu)-copper (Cu) junction, and may also be connected to each other through a solder junction if necessary. If necessary, the first and second cavities H1 and H2 may have different widths in a cross-sectional view. For example, the second cavity H2 may be wider than the first cavity H1 in a cross-sectional view. Correspondingly, the semiconductor device 150 and the metal block 160 may also have different widths in a cross-sectional view. For example, the metal block 160 may be wider than the semiconductor device 150 in a cross-sectional view. In this way, after forming the first and second cavities H1 and H2 separately, the semiconductor device 150 and the metal block 160 may be disposed and connected to each other using connections of metal vias. In this case as well, all of the above-described effects can be achieved. Other redundant descriptions will be omitted.

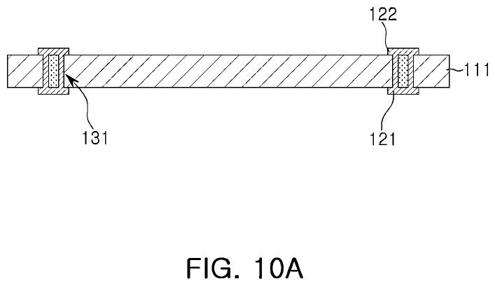

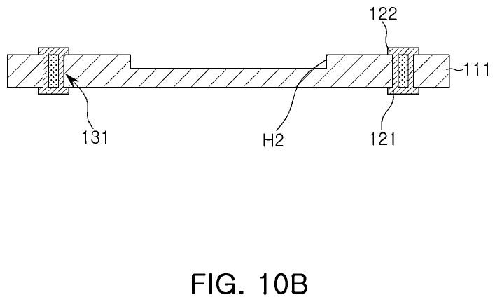

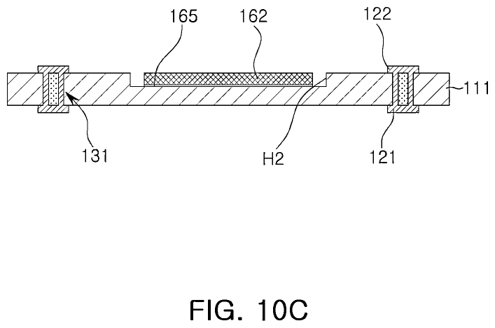

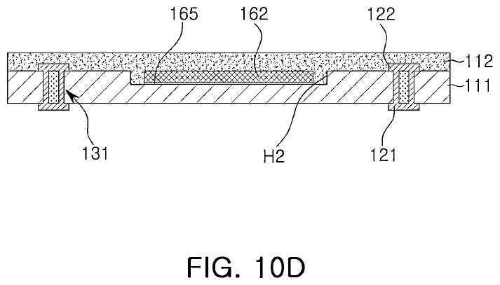

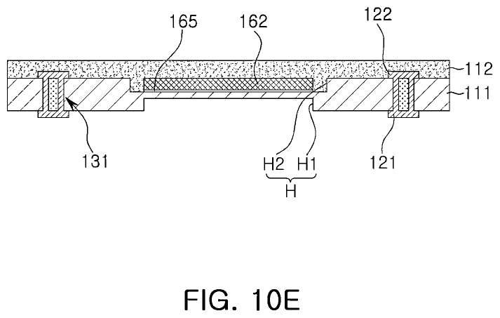

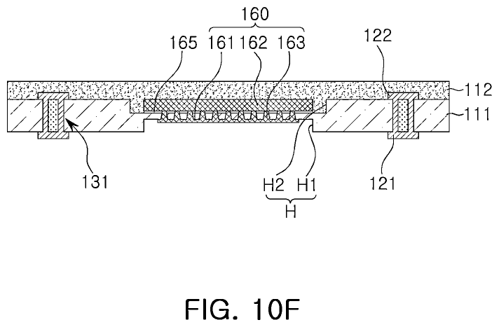

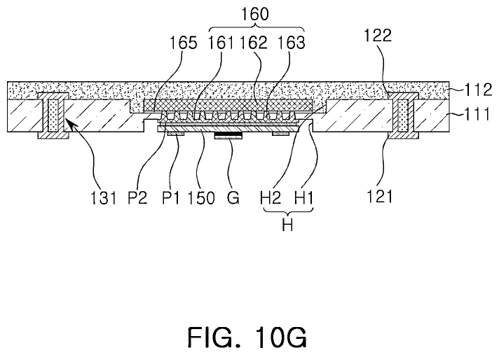

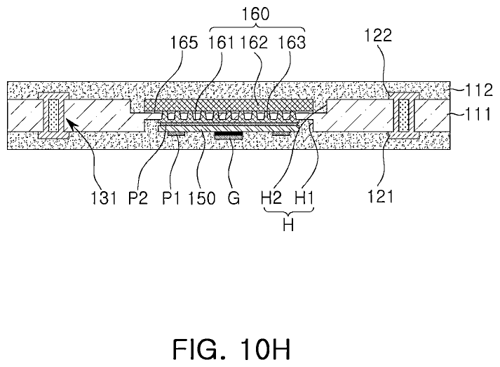

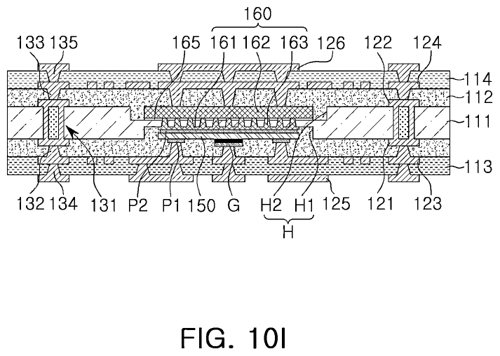

FIGS. 10A to 10I are schematic cross-sectional views illustrating examples of processes for manufacturing the printed circuit board of FIG. 9.

Referring to FIG. 10A, a substrate 111 may be prepared, and first and second wiring layers 121 and 122 and a first via layer 131 may be formed on and in the substrate 111. The substrate 111 may have various types of materials as described above, and the type of material may be selected according to need. A through-via hole for forming the first via layer 131 may be formed by any of various methods such as a laser drilling process, a mechanical drilling process, a chemical etching process, and a blasting process, depending on the material of the substrate 111. The first and second wiring layers 121 and 122 may be formed by a plating process. The first via layer 131 may be formed through a plating process and, if necessary, a plugging process.

Referring to FIG. 10B, a second cavity H2 may be formed in the substrate 111. The second cavity H2 may be a blind cavity penetrating a portion of the substrate 111 from the upper surface of the substrate 111. The second cavity H2 may be formed by any of various methods, such as a laser drilling process, a mechanical drilling process, a chemical etching process, and a blasting process, depending on the material of the substrate 111.

Referring to FIG. 10C, a second metal block 162 may be disposed in the second cavity H2. For example, the second metal block 162 may be attached onto a bottom surface of the second cavity H2 using an adhesive 165 such as a DAF.

Referring to FIG. 10D, the substrate 111 and the second metal block 162 may be buried by a first layer of the first insulating layer 112. For example, the substrate 111 and the second metal block 162 may be covered by stacking the first layer of the first insulating layer 112 on the substrate 111.

Referring to FIG. 10E, a first cavity H1 may be formed in the substrate 111. The first cavity H1 may be a blind cavity penetrating another portion of the substrate 111 from the lower surface of the substrate 111. The first cavity H1 and the second cavity H2 may be separated from each other by the substrate 111. The second cavity H2 may be formed by any of various methods, such as a laser drilling process, a mechanical drilling process, a chemical etching process, and a blasting process, depending on the material of the substrate 111.

Referring to FIG. 10F, a first metal block 161 may be formed in the first cavity H1, and a metal via 163 may be formed in the substrate 111 between the first and second cavities H1 and H2, to connect the first and second metal blocks 161 and 162. The metal via 163 may penetrate the substrate 111 and the adhesive 165 at once. A via hole for the metal via 163 may be formed through any of various processes, such as a laser drilling process and a mechanical drilling process. The first metal block 161 and the metal via 163 may be formed through a plating process. For example, each of the first metal block 161 and the metal via 163 may include a seed metal layer and a plating metal layer formed on the seed metal layer.

Referring to FIG. 10G, a semiconductor device 150 may be disposed in the first cavity H1. For example, the semiconductor device 150 may be disposed in the first cavity H1 in such a manner that the second metal pad P2 of the semiconductor device 150 is connected to the first metal block 161.

Referring to FIG. 10H, the substrate 111, the first metal block 161, and the semiconductor device 150 may be buried by a second layer of the first insulating layer 112. For example, the substrate 111, the first metal block 161, and the semiconductor device 150 may be covered by stacking the second layer of the first insulating layer 112 on the substrate 111.

Referring to FIG. 10I, third and fourth wiring layers 123 and 124 and second and third via layers 132 and 133 may be formed on and in the first insulating layer 112. Via holes for forming the second and third via layers 132 and 133 may be formed by laser processing, mechanical drilling, or the like. The third and fourth wiring layers 123 and 124 and the second and third via layers 132 and 133 may be formed through a plating process. In addition, a build-up process may be performed, if necessary, to build second and third insulating layers 113 and 114, fifth and sixth wiring layers 125 and 126, and fourth and fifth via layers 134 and 135.

The above-described printed circuit board 100D according to another example may be manufactured through a series of processes, and other redundant descriptions will be omitted.

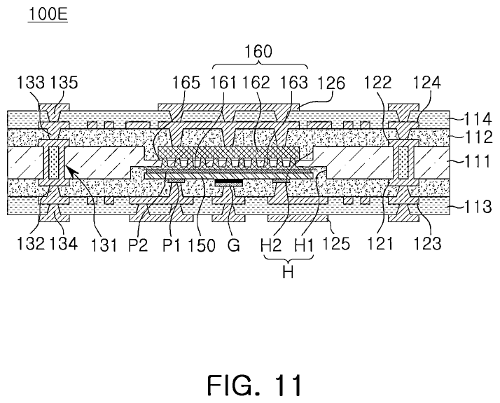

FIG. 11 is a schematic cross-sectional view illustrating a printed circuit board according to another example.

Referring to FIG. 11, in a printed circuit board 100E according to another example when compared to the above-described printed circuit board 100D according to another example, the first cavity H1 may be wider than the second cavity H2 in a cross-sectional view. Correspondingly, the semiconductor device 150 may be wider than the metal block 160 in a cross-sectional view. For example, the sizes of the first and second cavities H1 and H2 may be variously formed according to the sizes of the semiconductor device 150 and the metal block 160. In this case as well, all of the above-described effects can be achieved. Other redundant descriptions will be omitted.

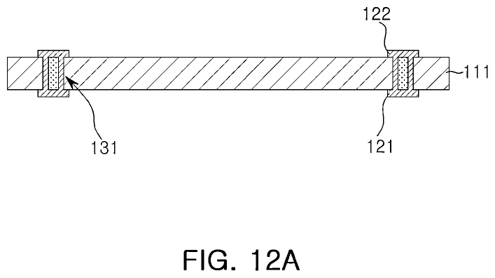

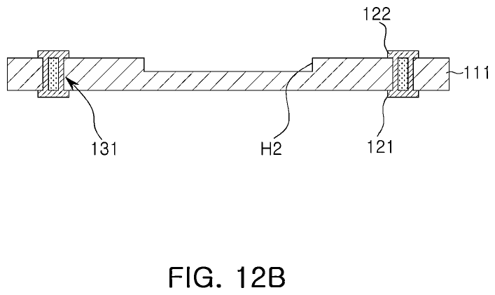

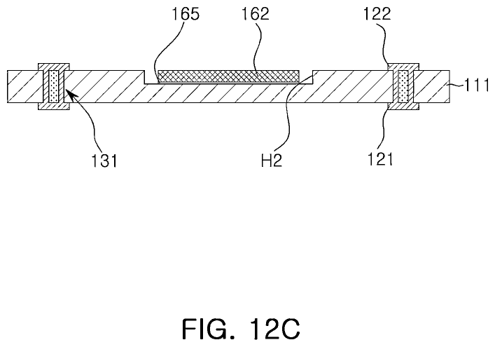

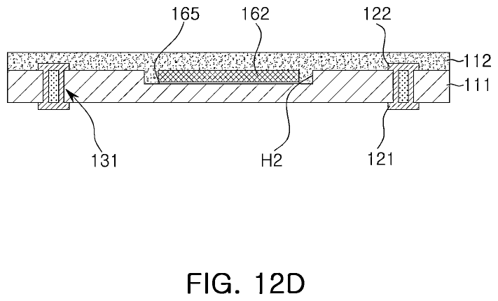

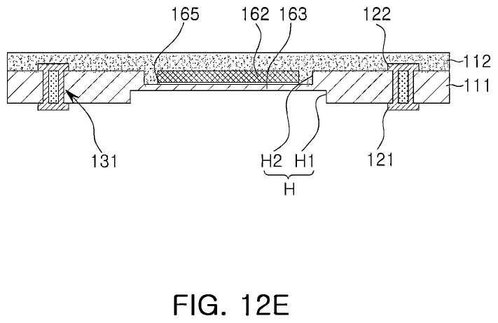

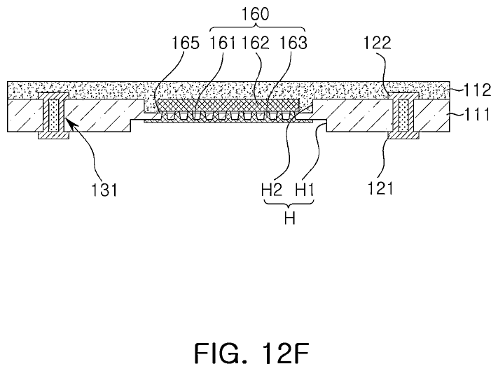

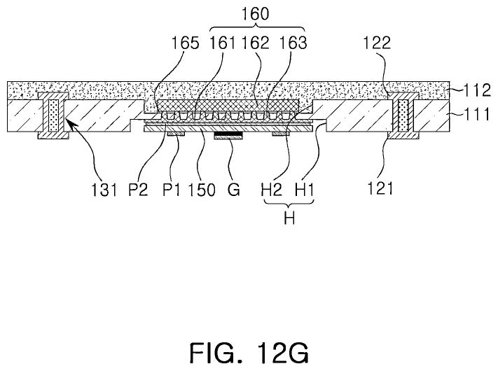

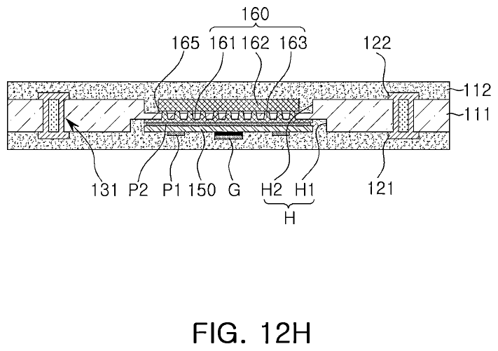

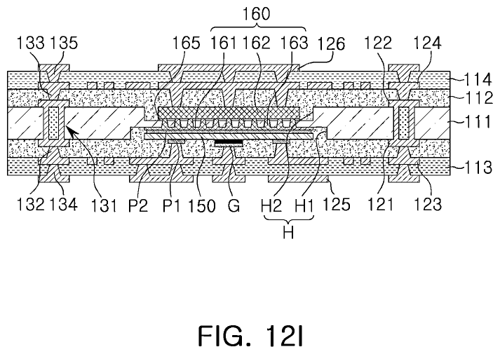

FIGS. 12A to 12I are schematic cross-sectional views illustrating examples of processes for manufacturing the printed circuit board of FIG. 11.

Referring to FIGS. 12A to 12I, the printed circuit board 100E according to another example may be manufactured through processes that are substantially the same as the above-described processes with reference to FIGS. 10A to 10I, except that the sizes of the first and second cavities H1 and H2 and the sizes of the semiconductor device 150 and the first and second metal blocks 161 and 162 disposed in the first and second cavities H1 and H2 are different.

The above-described printed circuit board 100E according to another example may be manufactured through a series of processes, and other redundant descriptions will be omitted.

As set forth above, as one of the several effects of the present disclosure, it is possible to provide a printed circuit board in which a semiconductor device, e.g., a power device, is embedded.

As another one of the several effects of the present disclosure, it is possible to provide a printed circuit board capable of reducing power loss by reducing a parasitic resistance of a power device.

As another one of the several effects of the present disclosure, it is possible to provide a printed circuit board having improved heat dissipation characteristics by smoothly dissipating heat from a power device.

In the present disclosure, the expression “cover” may refer to not only “entirely cover” but also “at least partially cover,” and may also refer to “directly cover” but also “indirectly cover.” In addition, the expression “fill” may refer to not only “completely fill” but also “at least partially fill,” and may also refer to “approximately fill.” For example, the expression “fill” may be interpreted to include a case in which there are some pores or voids. In addition, the expression “surround” may refer to not only “completely surround” but also “partially surround,” and may also refer to “approximately surround.”

In the present disclosure, an object being “disposed in a cavity” may refer to not only a case where the object is completely disposed in the cavity, but also a case where an object partially protrudes upward or downward in a cross-sectional view. For example, if an object is disposed in a cavity in a plan view, this may be interpreted in a broader sense.

In the present disclosure, process errors, position deviations, measurement errors, and the like that occur in a manufacturing process may be actually considered.

In the present disclosure, the same insulating material may refer to not only the exact same insulating material but also the same type of insulating material. Therefore, insulating materials may be slightly different in their specific composition ratios, while having substantially the same composition.

In the present disclosure, a cross-sectional view may refer to a cross-sectional shape of an object when cut vertically or a cross-sectional shape of an object when viewed from a side view. In addition, a plan view may refer to a planar shape of an object when cut horizontally or a planar shape of an object when viewed from a top view or from a bottom view.

In the present disclosure, for convenience, based on cross sections of the drawings, a lower side, a lower portion, a lower surface, and the like refer to a downward direction, while an upper side, an upper portion, an upper surface, and the like refer to a direction opposite to the downward direction. However, these directions are defined for convenience of explanation, and the scope of the claims is not particularly limited by the definitions of the directions. The concepts of “up” and “down” may be changed at any time.

In the present disclosure, “being connected” has a concept that includes not only “being direct connected” but also “being indirectly connected through an adhesive layer or the like.” In addition, “being electrically connected” has a concept that includes both “being physically connected” and “being physically disconnected.” In addition, the expressions “first,” “second,” and the like are used to distinguish one component from another component, and do not limit the order and/or importance of the components. In some cases, a first component may be referred to as a second component, and similarly, a second component may be referred to as a first component without departing from the scope of right.

The expression “an example” used in the present disclosure does not refer to the same embodiment, but is used to emphasize and explain a different unique feature. However, the examples presented above may be implemented in combination with features of other examples. For example, even if a matter explained in a specific example is not explained in another example, the matter explained in the specific example may be understood as an explanation related to another example, as long as there is no explanation that is contrary to or contradicts the matter in another example.

In the present disclosure, each of a thickness, a width, a length, a depth, and the like may be measured using a scanning microscope or an optical microscope based on a cross-section obtained by polishing or cutting a printed circuit board. The cut section may be a vertical section or a horizontal section, and each value may be measured based on the required cut section. If the value is not constant, the value may be determined as an average value of values measured at five random points. A width of an upper and/or lower end of a via may be measured in a cross-section view when a the substrate is cut along the central axis of the via in the thickness direction. A depth of a via may be measured as a distance from an upper end to a lower end of each object in a cross-sectional view when a substrate is cut along the central axis of each object in the thickness direction.

An average thickness, an average diameter, an average depth, or the like may be calculated as an average value of values measured at five random points. In a case where each opening has a tapered shape, a diameter of each opening may be calculated as an average value of diameters on the uppermost and lowermost sides of each opening.

The terms used in the present disclosure are used only to describe examples, and are not intended to limit the present disclosure. At this time, singular expressions include plural expressions, unless the context clearly indicates otherwise.

While exemplary embodiments have been shown and described above, it will be apparent to those skilled in the art that modifications and variations could be made without departing from the scope of the present disclosure as defined by the appended claims.

What is claimed is:

1. A printed circuit board comprising:
a substrate having a cavity;
a semiconductor device at least partially disposed in the cavity, with a first metal pad being disposed on a lower side of the semiconductor device and a second metal pad being disposed on an upper side of the semiconductor device;
a metal block at least partially disposed in the cavity, the metal block being connected to the second metal pad; and
a first insulating layer covering at least a portion of each of the substrate, the semiconductor device, and the metal block, and filling at least a portion of the cavity.

2. The printed circuit board according to claim 1, wherein the semiconductor device includes a power MOSFET,
the first metal pad includes a source pad,
the second metal pad includes a drain pad, and
a gate is further disposed on the lower side of the semiconductor device.

3. The printed circuit board according to claim 1, wherein the metal block is directly connected to the second metal pad.

4. The printed circuit board according to claim 3, wherein each of the second metal pad and the metal block includes copper, and the copper of the second metal pad and the copper of the metal block are joined to each other and directly connected to each other.

5. The printed circuit board according to claim 1, wherein the cavity penetrates between upper and lower surfaces of the substrate in a thickness direction, and the metal block is attached to the upper side of the semiconductor device, and at least a portion of the metal block is disposed in the cavity together with the semiconductor device.

6. The printed circuit board according to claim 1, wherein the cavity includes a first cavity penetrating at least a portion of the substrate from a lower surface of the substrate in a thickness direction, and a second cavity penetrating at least another portion of the substrate from an upper surface of the substrate in the thickness direction,
at least a portion of the semiconductor device is disposed in the first cavity, and
at least a portion of the metal block is disposed in the second cavity.

7. The printed circuit board according to claim 6, wherein the first and second cavities have different widths in a cross-sectional view, and
the semiconductor device and the metal block have different widths in a cross-sectional view.

8. The printed circuit board according to claim 6, wherein the first and second cavities are connected to each other in the thickness direction.

9. The printed circuit board according to claim 6, wherein the substrate is disposed between the first and second cavities to separate the first and second cavities from each other.

10. The printed circuit board according to claim 9, wherein the metal block includes a first metal block at least partially disposed in the first cavity, the first metal block being connected to the second metal pad, a second metal block of at least partially disposed in the second cavity, the second metal block being attached onto the substrate disposed between the first and second cavities through an adhesive, and a metal via penetrating the substrate disposed between the first and second cavities and the adhesive and connecting the first and second metal blocks to each other.

11. The printed circuit board according to claim 1, further comprising:
a first wiring layer disposed on a lower surface of the substrate;
a second wiring layer disposed on an upper surface of the substrate; and
a first via layer penetrating the substrate, and connecting the first and second wiring layers to each other.

12. The printed circuit board according to claim 11, further comprising:
a third wiring layer disposed on a lower surface of the first insulating layer;
a second via layer penetrating at least a portion of the first insulating layer on a lower side thereof, and connecting the third wiring layer to each of the first wiring layer and the first metal pad;
a fourth wiring layer disposed on an upper surface of the first insulating layer; and
a third via layer penetrating at least a portion of the first insulating layer on an upper side thereof, and connecting the fourth wiring layer to each of the second wiring layer and the second metal pad.

13. The printed circuit board according to claim 1, wherein the substrate includes an organic core layer, a glass core layer, a metal core layer, a silicon core layer, or a ceramic core layer.

14. A printed circuit board comprising:
a substrate having a through-cavity;
a laminate at least partially disposed in the through-cavity, the laminate including a power device with a first metal pad and a gate being disposed on a first side of the power device and a second metal pad being disposed on a second side of the power device, and a metal block disposed on the power device and contacting the second metal pad; and
an insulating layer covering at least a portion of each of the substrate and the laminate, and filling at least a portion of the through-cavity.

15. The printed circuit board according to claim 14, further comprising:
first and second metal pattern layers disposed on the first side and the second side of the insulating layer, respectively;
a first metal via penetrating at least a portion of the insulating layer, and connecting at least a portion of the first metal pattern layer to the first metal pad;
a second metal via penetrating at least another portion of the insulating layer, and connecting at least another portion of the first metal pattern layer to the gate; and
a third metal via penetrating at least another portion of the insulating layer, and connecting at least a portion of the second metal pattern layer to the metal block.

16. The printed circuit board according to claim 14, wherein the metal block is thicker than the power device.

17. A printed circuit board, comprising:
a substrate having a first cavity disposed in a first surface thereof and a second cavity disposed in a second surface thereof, the first and second cavities at least partially overlapping in a plan view;
a semiconductor device disposed at least partially in the first cavity and having a first metal pad disposed on a first side thereof and a second metal pad disposed on a second side thereof;
a metal block at least partially disposed in the second cavity and directly contacting the second metal pad of the semiconductor device; and
a first insulating layer disposed on the first and second surfaces of the substrate, at least partially covering the substrate, the semiconductor device and the metal block at least partially filling the first and second cavities.

18. The printed circuit board of claim 17, wherein at least a portion of the first and second cavities are connected in a cross-sectional view to form at least one through-hole penetrating through the substrate.

19. The printed circuit board of claim 17, wherein the first and second cavities have different widths in a cross-sectional view, and
the semiconductor device and the metal block have different widths in the cross-sectional view.

20. The printed circuit board of claim 17, further comprising:
a first wiring layer disposed on the first surface of the substrate;
a second wiring layer disposed on the second surface of the substrate; and
a first via layer penetrating the substrate, and connecting the first and second wiring layers to each other.
